(19) United States
(12) Patent Application Publication
(10) Pub. No.: US 2026/0089872 A1
(43) Pub. Date: Mar. 26, 2026

(54) METHOD OF DIMM COOLING WITH GAS AND INFLATABLE COLD PLATE

(71) Applicant: Lenovo Global Technology (United States) Inc., Morrisville, NC (US)

(72) Inventors: Shreekanth Murthy Muthigi, Bangalore (IN); Vinod Kamath, Raleigh, NC (US)

(21) Appl. No.: 18/897,878

(22) Filed: Sep. 26, 2024

(51) Int. Cl. H05K 7/20

(52) U.S. Cl. CPC H05K 7/20163; H05K 7/20727

(57) ABSTRACT

An apparatus for DIMM cooling includes an inflatable cold plate configured for placement in a slot between two memory cards connected to a motherboard of a computing device. The inflatable cold plate expands to contact the two memory cards in response to pressure from a cooling fluid and the inflatable cold plate is configured to transfer heat from the two memory cards to the cooling fluid. The inflatable cold plate is in fluid communication with a fluid pump configured to pump the cooling fluid through the inflatable cold plate at a sufficient pressure to pressurize the inflatable cold plate against the two memory cards and to circulate the cooling fluid through the inflatable cold plate to transfer heat from the inflatable cold plate.

### FIELD

The subject matter disclosed herein relates to cooling of computing devices and more particularly relates to cooling of memory cards, such as dual inline memory modules (“DIMMs”), in computing devices.

### BACKGROUND

Cooling of DIMM modules is challenging because of a small space between DIMMs in a narrow DIMM pitch of 300 millimeters and a high volumetric flow rate required. One of the best known solutions for DIMM cooling today only addresses 330-350 mil DIMM pitch cooling. Due to poor thermal conductivity of air, often a liquid cooling loop is used with a coolant such as PG25 (mixture of water and glycol) is used to pass in a cold plate that contacts DIMMs on either side. The liquid cooling of DIMMs requires that the cold plate be made of copper and uses thermal gap pads attached between cold plate and the DIMMs, which adds complexity due to difficulty of DIMM insertion and extraction. The cost of a cold plate for DIMM cooling infrastructure is high.

### BRIEF SUMMARY

An apparatus for DIMM cooling includes an inflatable cold plate configured for placement in a slot between two memory cards connected to a motherboard of a computing device. The inflatable cold plate expands to contact the two memory cards in response to pressure from a cooling fluid and the inflatable cold plate is configured to transfer heat from the two memory cards to the cooling fluid. The inflatable cold plate is in fluid communication with a fluid pump configured to pump the cooling fluid through the inflatable cold plate at a sufficient pressure to pressurize the inflatable cold plate against the two memory cards and to circulate the cooling fluid through the inflatable cold plate to transfer heat from the inflatable cold plate.

A system for DIMM cooling with an inflatable cold plate includes a fluid pump and a computing device. The computing device includes a motherboard, at least two memory cards connected to the motherboard, and at least one inflatable cold plate configured for placement in a slot between two memory cards of the at least two memory cards connected to the motherboard. The at least one inflatable cold plate expands to contact the two memory cards in response to pressure from a cooling fluid and the at least one inflatable cold plate is configured to transfer heat from the two memory cards to the cooling fluid. The at least one inflatable cold plate is in fluid communication with the fluid pump configured to pump the cooling fluid through the inflatable cold plate at a sufficient pressure to pressurize the inflatable cold plate against the two memory cards and circulate the cooling fluid through the inflatable cold plate to transfer heat from the inflatable cold plate.

Another apparatus for DIMM cooling with an inflatable cold plate includes an inflatable cold plate configured for placement in a slot between two DIMMs connected to a motherboard of a computing device. The inflatable cold plate expands to contact the two DIMMs in response to pressure from a cooling loop and the inflatable cold plate is configured to transfer heat from the two DIMMs to the cooling loop. The inflatable cold plate is in fluid communication with a fluid pump configured to pump helium in a cooling loop through the inflatable cold plate at a sufficient pressure to pressurize the inflatable cold plate against the two DIMMs and to circulate the helium through the cooling loop of the inflatable cold plate to transfer heat from the inflatable cold plate to an external heat exchanger within the cooling loop.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a schematic block diagram illustrating a system with a motherboard with two servers with an inflatable cold plate for cooling between memory cards, according to various embodiments;

FIG. 2 is a schematic block diagram illustrating another system with a motherboard with two servers with an inflatable cold plate for cooling between memory cards with an open cooling loop, according to various embodiments;

FIG. 3A is a schematic block diagram illustrating memory cards with an uninflated inflatable cold plate for cooling in each slot between the memory cards, according to various embodiments;

FIG. 3B is a schematic block diagram illustrating the memory cards and inflatable cold plates of FIG. 3A where the inflatable cold plates are inflated, according to various embodiments;

FIG. 4A is a schematic block diagram illustrating a cross section of memory cards with an uninflated inflatable cold plate for cooling with a V-shaped end, according to various embodiments;

FIG. 4B is a schematic block diagram illustrating the memory cards and inflatable cold plates of FIG. 4A where the inflatable cold plates are inflated, according to various embodiments;

FIG. 5A is a schematic block diagram illustrating a cross section of memory cards with an uninflated inflatable cold plate for cooling with a bellows-type end, according to various embodiments;

FIG. 5B is a schematic block diagram illustrating the memory cards and inflatable cold plates of FIG. 5A where the inflatable cold plates are inflated, according to various embodiments;

FIG. 6A is a schematic block diagram illustrating a cross section of memory cards with another uninflated inflatable cold plate for cooling with a frame and expandable connectors, according to various embodiments;

FIG. 6B is a schematic block diagram illustrating the memory cards and inflatable cold plates of FIG. 6A where the inflatable cold plates are inflated, according to various embodiments;

FIG. 7A is a schematic block diagram illustrating a cross section of memory cards with another uninflated inflatable cold plate for cooling similar to the inflatable cold plate of FIGS. 5A and 5B with sides with variable thickness to match components of the memory cards, according to various embodiments; and

FIG. 7B is a schematic block diagram illustrating the memory cards and inflatable cold plates of FIG. 7A where the inflatable cold plates are inflated, according to various embodiments.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of designs, options, materials, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C. As used herein, “a member selected from the group consisting of A, B, and C,” includes one and only one of A, B, or C, and excludes combinations of A, B, and C.” As used herein, “a member selected from the group consisting of A, B, and C and combinations thereof” includes only A, only B, only C, a combination of A and B, a combination of B and C, a combination of A and C or a combination of A, B and C.

An apparatus for DIMM cooling includes an inflatable cold plate configured for placement in a slot between two memory cards connected to a motherboard of a computing device. The inflatable cold plate expands to contact the two memory cards in response to pressure from a cooling fluid and the inflatable cold plate is configured to transfer heat from the two memory cards to the cooling fluid. The inflatable cold plate is in fluid communication with a fluid pump configured to pump the cooling fluid through the inflatable cold plate at a sufficient pressure to pressurize the inflatable cold plate against the two memory cards and to circulate the cooling fluid through the inflatable cold plate to transfer heat from the inflatable cold plate.

In some embodiments, the two memory cards are two DIMMs. In other embodiments, the inflatable cold plate is configured to expand in a direction towards a side of each of the two memory cards in response to the fluid pump pumping the cooling fluid. In other embodiments, one or both surfaces facing the two memory cards include a compliant material configured to form to an irregular surface of each of the two memory cards. In other embodiments, one or both surfaces facing the two memory cards include an irregular shape configured to form to a corresponding irregular surface of each of the two memory cards.

In some embodiments, sides of the inflatable cold plate other than surfaces facing the two memory cards expand less than the surfaces facing the two memory cards. In other embodiments, the sides of the of the inflatable cold plate other than surfaces facing the two memory cards are configured to be rigid. In other embodiments, the apparatus includes the fluid pump and a heat exchanger. The heat exchanger is positioned in a cooling loop in fluid communication with the fluid pump and the inflatable cold plate and positioned to remove heat from the cooling fluid. In other embodiments, the heat exchanger is a first heat exchanger and is coupled to a secondary cooling loop and the secondary cooling loop is coupled to a secondary heat exchanger configured to expel heat to air in a location away from the computing device. In other embodiments, the heat exchanger is configured to expel heat to air in a location away from the computing device.

In some embodiments, the apparatus includes the fluid pump and the cooling fluid is air and the fluid pump and inflatable cold plate are in fluid communication via an open loop. Air exiting the inflatable cold plate is expelled to a location external to the computing device and/or a space housing the computing device. In other embodiments, the inflatable cold plate includes one or more gap pads positioned on one or both surfaces of the inflatable cold plate facing the two memory cards to contact one or more components of at least one of the two memory cards. In other embodiments, the cooling fluid is helium.

A system for DIMM cooling with an inflatable cold plate includes a fluid pump and a computing device. The computing device includes a motherboard, at least two memory cards connected to the motherboard, and at least one inflatable cold plate configured for placement in a slot between two memory cards of the at least two memory cards connected to the motherboard. The at least one inflatable cold plate expands to contact the two memory cards in response to pressure from a cooling fluid and the at least one inflatable cold plate is configured to transfer heat from the two memory cards to the cooling fluid. The at least one inflatable cold plate is in fluid communication with the fluid pump configured to pump the cooling fluid through the inflatable cold plate at a sufficient pressure to pressurize the inflatable cold plate against the two memory cards and circulate the cooling fluid through the inflatable cold plate to transfer heat from the inflatable cold plate.

In some embodiments, the system includes a heat exchanger. The heat exchanger is positioned in a cooling loop in fluid communication with the fluid pump and the inflatable cold plate and is positioned to remove heat from the cooling fluid. In other embodiments, the heat exchanger is a first heat exchanger and is coupled to a secondary cooling loop and the secondary cooling loop is coupled to a secondary heat exchanger that is configured to expel heat to air in a location away from the computing device. In other embodiments, the heat exchanger is configured to expel heat to air in a location away from the computing device. In other embodiments, the cooling fluid is air and the fluid pump and inflatable cold plate are in fluid communication via an open loop. Air exiting the inflatable cold plate is expelled to a location external to the computing device and/or a space housing the computing device. In other embodiments, the cooling fluid is helium.

Another apparatus for DIMM cooling with an inflatable cold plate includes an inflatable cold plate configured for placement in a slot between two DIMMs connected to a motherboard of a computing device. The inflatable cold plate expands to contact the two DIMMs in response to pressure from a cooling loop and the inflatable cold plate is configured to transfer heat from the two DIMMs to the cooling loop. The inflatable cold plate is in fluid communication with a fluid pump configured to pump helium in a cooling loop through the inflatable cold plate at a sufficient pressure to pressurize the inflatable cold plate against the two DIMMs and to circulate the helium through the cooling loop of the inflatable cold plate to transfer heat from the inflatable cold plate to an external heat exchanger within the cooling loop.

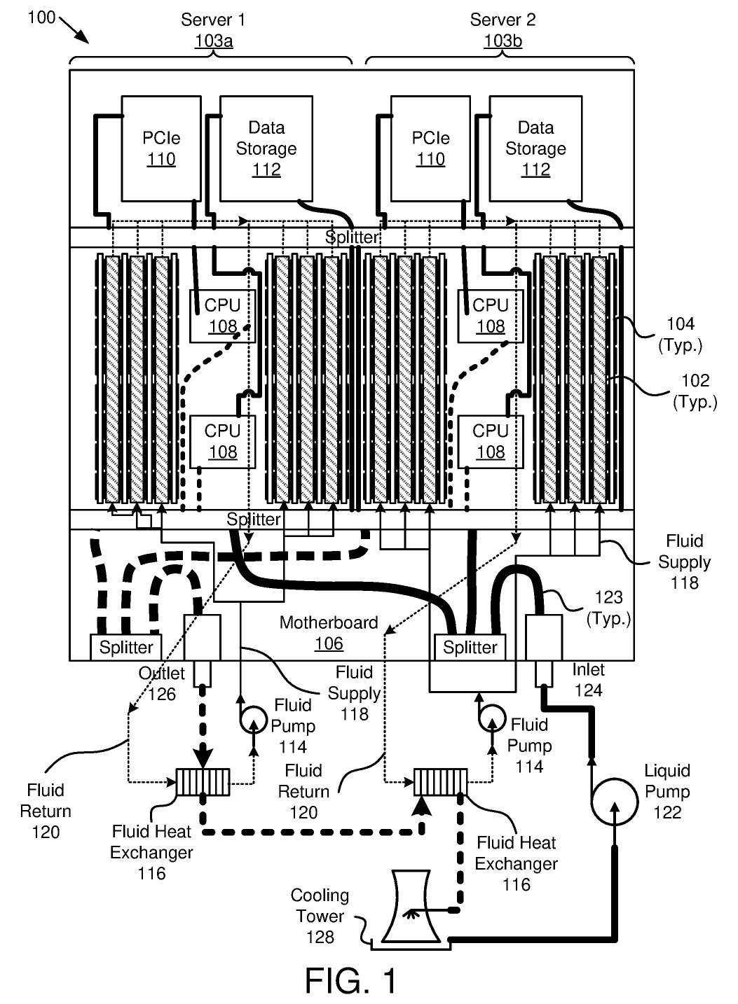

FIG. 1 is a schematic block diagram illustrating a system 100 with a motherboard 106 with two servers 103a, 103b with an inflatable cold plate for cooling between memory cards 104, according to various embodiments. The system 100 includes a motherboard 106 of a computing device. The motherboard 106, in the depicted embodiment, is for two servers 103a, 103b (generically or collectively 103) next to each other. Other embodiments include a motherboard 106 with single server 103. Each server 103 includes one or more central processing units (“CPUs”) and each server 103 depicted in FIG. 1 includes two CPUs 108. Each server 103 also includes a Peripheral Component Interconnect Express (“PCIe”) card 110 and data storage 112. The data storage 112 is non-volatile data storage, such a flash memory, a hard disk drive (“HDD”), or the like. The embodiments described herein also anticipate other computing devices with a slot between memory cards 104.

Each server also includes memory cards 104 on either side of the CPUs 108. In some embodiments, the memory cards 104 are dual in-line memory modules (“DIMMs”). In other embodiments, the memory cards 104 are other types of memory. The memory cards 104 are plugged into the motherboard 106 and are typically in a parallel configuration with a space between the memory cards 104 forming slots that allows for air flow from fans (not shown) in a direction in-line with the slots between the memory cards 104. In past designs, memory card cooling depended on forced air cooling. In more recent designs, servers are liquid cooled and liquid cooling lines 123 (depicted as thick dark lines) enter the servers 103 at a liquid inlet 124, are split into smaller liquid cooling lines 123, and then are routed through cold plated between the memory cards, are routed near the CPUs 108, the memory cards (previous designs), the PCIe cards 110, the data storage 112, and other components of the servers 103, and then exit a liquid outlet 126.

The liquid cooling lines 123 that are part of a liquid cooling system typically circulate a liquid, such as water, glycol, or the like. The liquid cooling system includes a liquid pump 122 that sends liquid into the servers 103 via the liquid inlet 124 and return lines from the liquid outlet 126, which then feeds to some type of heat exchanger before returning to the liquid pump 122. In some embodiments, the heat exchanger is a cooling tower 128 that uses evaporative cooling. In other embodiments, the heat exchanger is a condenser with coils and a fan that circulates air over the coils. In other embodiments, the heat exchanger is another type known to those of skill in the art.

Note that the liquid pump 122 and cooling tower 128 are depicted as serving a single motherboard 106 in FIG. 1. One of skill in the art will recognize that a datacenter or other location with liquid cooling lines may include a liquid pump 122 serving multiple motherboards 106 in a rack, may serve multiple racks in a row, and may serve multiple rows. One of skill in the art will recognize various configurations and quantities of liquid pumps 122, cooling towers 128, routing of liquid cooling lines 123, etc.

The embodiments described herein include an inflatable cold plate 102 in each slot between memory cards 104 instead of a traditional cold plate between memory cards 104. The inflatable cold plates 102 expand to contact the memory cards 104 due to pressure from a fluid in the inflatable cold plates 102 and circulated via fluid supply and return lines 118, 120. Fluid passing through the inflatable cold plates 102 removes heat from the memory cards 104. In some embodiments, the fluid passing through the inflatable cold plates 102 and fluid supply and return lines 118, 120 is injected by a fluid pump 114 that provides sufficient pressure to pressurize the inflatable cold plate 102 against the two memory cards 102. As used herein, a sufficient pressure to pressurize the inflatable cold plate 102 against the two memory cards 102 means an amount of pressure to expand the sides of the inflatable cold plate 102 to at least contact components 302 of the memory cards 104 with enough surface area so that heat is transferred from the memory cards 104 to the inflatable cold plate 102 and to the fluid in the inflatable cold plate 102.

The inflatable cold plate 102 is designed to have a significant amount of contact with the components 302 of the memory cards to allow cooling of the memory cards 102 and to remove a specified amount of heat from the memory cards 104. In some embodiments, the fluid cooling system is designed to be below an upper pressure limit to avoid putting an unwanted amount of pressure onto the memory cards 104.

While FIG. 1 depicts inflatable cold plates 102 in slots between memory cards 104, in other embodiments, the motherboard 106 includes a vertical device (not shown) on the ends of the rows of memory cards 104 where the vertical device is parallel to the memory cards 104. In the embodiments, an inflatable cold plate 102 is placed between an end memory card 104 and the vertical device so that all sides of the memory cards 104 have cooling.

The fluid in the fluid supply lines 118 is split and fed into the inflatable cold plates 102 and then returned via fluid return lines 120 and exits the servers 103 and, in some embodiments, is fed into a fluid heat exchanger 116. The fluid heat exchanger 116, in the embodiments depicted in FIG. 1, is tied into the liquid cooling lines 123 where heat from the fluid return lines 120 is transferred to the liquid cooling lines 123 and transported to the cooling tower 128 or other heat exchanger. In other embodiments, the fluid heat exchanger 116 is independent of the liquid cooling system.

In some embodiments, the fluid of the cooling loop is a liquid, such as water or glycol. In some embodiments, the fluid is a gas, such as air or helium. In some embodiments, helium is chosen due to having about 6 times the thermal conductivity of air and about 5 times the specific heat of air. Helium is also readily available. Other gases with good thermal properties may also be used, such as hydrogen. The fluid supply lines 118 are depicted as thin, solid black lines with arrows and the fluid return lines 120 are depicted as thin, dashed black lines with arrows. Note that the transitions between solid fluid supply lines 118 and dashed fluid return lines 120 is arbitrary since the fluid supply lines 118 pick up heat as they go. The fluid supply lines 118 are split into multiple loops per side based on the number of inflatable cold plates 102 in the system 100 in FIG. 1. In some embodiments, the fluid supply lines 118 may split into additional lines to cool other components such as data storage 112, the PCIe cards 110, and/or the CPUs 108. The fluid supply lines 118 loop through the inflatable cold plates 102 between two memory cards 104. The fluid supply lines 118 and fluid return lines 120 are routed arbitrarily to show functionality and one of skill in the art will recognize other ways to route the fluid supply lines 118 and the fluid return lines 120, with splitters and other cooling line routing equipment as necessary.

Routing of the fluid supply and return lines 118, 120 in some embodiments, originate and terminate at one end of the motherboard 106, as in the system 100FIG. 1. In addition, the fluid supply lines 118 and the fluid return lines 120, in some embodiments, are split differently and routed differently than shown. The supply and return lines 118, 120 include one or more fluid pumps 114 that pump the cooling fluid through the fluid supply and return lines 118, 120 and the one or more fluid heat exchangers 116.

In some embodiments, the fluid supply and return lines 118, 120 are part of a closed loop at a particular pressure sufficient to expand the inflatable cold plates 102 enough to contact the memory cards 104 on either side of the inflatable cold plates 102. In some embodiments, the pressure is created by the fluid pumps 114. In some embodiments, a particular pressure in the inflatable cold plate 102 is controlled via an expansion valve, pressure relief valve, etc. (not shown) in the fluid return lines 120. In various embodiments, the fluid pressure and a particular fluid, and/or a flow rate are chosen to achieve a particular amount of cooling in the memory cards 104 so that heat is transferred from the memory cards 104 to the inflatable cold plates 102 and to the cooling fluid.

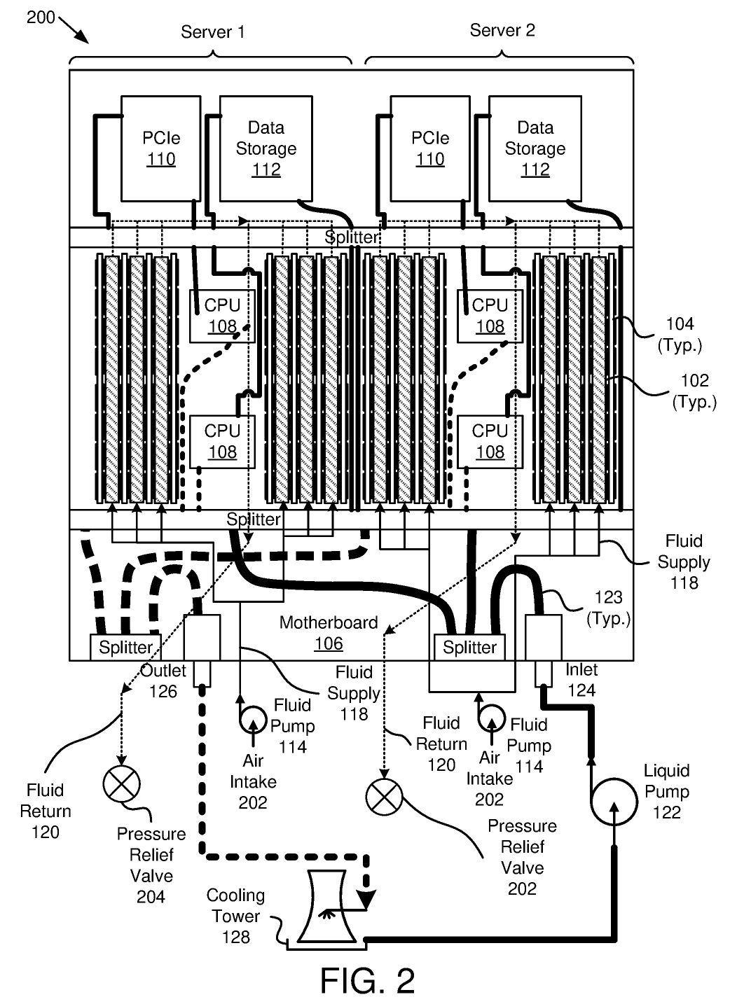

FIG. 2 is a schematic block diagram illustrating another system 200 with a motherboard 106 with two servers 103a, 103b with an inflatable cold plate 102 for cooling between memory cards 104 with an open cooling loop, according to various embodiments. The motherboard 106, servers 103a, 103b, inflatable cold plates 102, memory cards 104, CPUs 108, PCIe cards 110, data storage 112, fluid pumps 114, fluid supply lines 118, fluid return lines 120, liquid pump 122, liquid cooling lines 123, liquid inlet 124, liquid outlet 126, and cooling tower 128 are substantially similar to those described above in relation the system 100 of FIG. 1. The fluid cooling system is an open loop system with a working fluid of air. An air intake 202 draws in air into the fluid pump 114, which travels through the fluid supply lines 118 to the inflatable cold plates 102 and into the fluid return lines 120 to a pressure relief valve 204 where the air is expelled.

In some embodiments, the air intake 202 is located just outside the servers 103 and draws in air from the space of the servers 103. In other embodiments, the air intakes 202 are located to draw in refrigerated air, such as air from an air conditioning system. In other embodiments, the air intakes 202 are located outside of a room with the servers 103. One of skill in the art will recognize suitable locations for the air intakes 202.

In some embodiments, the pressure relief valves are configured to allow air to escape at a pressure setting where the pressure setting is selected at a value where the inflatable cold plates 102 are inflated. When air from the fluid return lines has a pressure below the pressure setting, the pressure relief valve 204 will stop or slow air coming from the inflatable cold plates 102. In some embodiments, fluid return lines 120 are sized to act as pressure relief valves 204 and the fluid pump 114 includes a pressure regulator set to a pressure sufficient to inflate the inflatable cold plates 102. In some embodiments, the pressure relief valves 204 are located just outside the motherboard 106. In other embodiments, the pressure relief valves 204 are located relative to air conditioning return air intakes so that air from the pressure relief valves 204 will exit into the return air intakes. In other embodiments, the pressure relief valves 204 are located to expel air outside of a room with the servers 103 and/or outside of the building housing the servers 103. One of skill in the art will recognize other suitable locations for the pressure relief valves 204. While the system 200 of FIG. 2 is described above with a working fluid of air, in other embodiments, the working fluid is another fluid, such as water or other non-toxic fluid that can be expelled into the atmosphere.

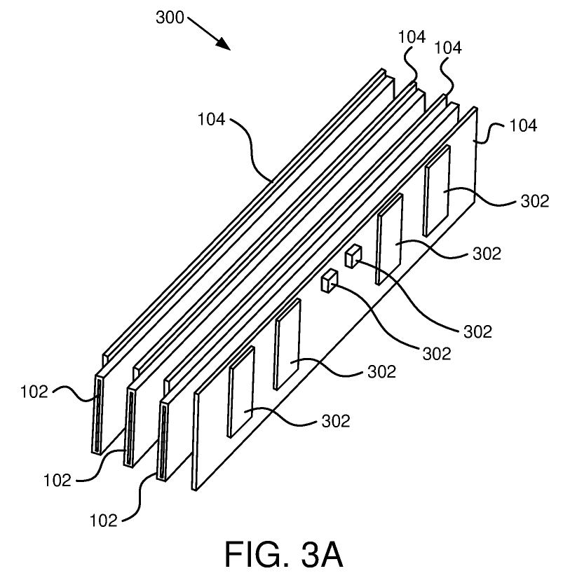

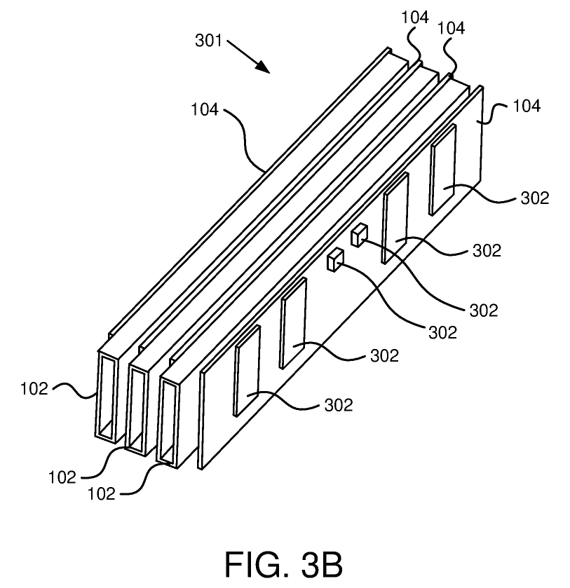

FIG. 3A is a schematic diagram 300 illustrating memory cards 104 with an uninflated inflatable cold plate 102 for cooling in each slot between the memory cards 104, according to various embodiments. FIG. 3B is a schematic block diagram 301 illustrating the memory cards 104 and inflatable cold plates 102 of FIG. 3A where the inflatable cold plates 102 are inflated, according to various embodiments. The inflatable cold plates 102 are designed to inflate upon pressurization with the fluid in the fluid supply lines 118. Prior to pressurization, the uninflated inflatable cold plates 102, in some embodiments, are designed to slide between memory cards 104 without catching on or putting pressure on components 302 on the memory cards 104, which is an advantage over traditional cold plates. In other embodiments, the inflatable cold plates 102 are sized when uninflated to have a friction fit when slid between memory cards 104 and increase pressure on the components 302 and memory cards 104 when inflated.

FIG. 3B illustrates when the inflatable cold plate 102 is pressurized by fluid in the cooling loop to contact the two memory cards 104. In some embodiments, the memory cards 104 are dual in-line memory modules (DIMMs). In some embodiments, the memory cards 104 have components 302 with various depths, lengths, and widths. In some embodiments, the components 302 are found on both sides of the memory cards 104. When pressurized by the cooling fluid, the inflatable cold plate 102 will come in contact with some or all of the components 302 to extract heat from memory cards 104. As shown by FIG. 3B, in some embodiments the inflatable cold plate 102 expands from pressure in a direction towards the memory cards 104.

In some embodiments, the inflatable cold plate 102 has a rectangular cross-section where the cross section in in a plane along the length and height of the slot between memory cards 104 and parallel to the memory cards 104. In some embodiments, the inflatable cold plate 102 maintains its rectangular shape in this plane along the direction of the slot as it is pressurized by the cooling fluid of the cooling loop. In some embodiments, the inflatable cold plate 102 includes a frame that prevents expansion in directions other than towards the memory cards 104. In some embodiments, the frame is rigid or is more rigid than material that expands towards the memory cards 104. In other embodiments, the inflatable cold plate 102 is made from a unitary material that is thicker on the ends, top and bottom and thinner on the sides facing the memory cards 104 so that expansion is substantially towards the memory cards 104 and minimized in directions other than towards the memory cards 104.

In other embodiments, the inflatable cold plate 102 has some expansion in directions other than towards the memory cards 104. In such embodiments, the expansion may be minimal to prevent the inflatable cold plate 102 from moving or creeping out of place. In some embodiments, the inflatable cold plate 102 is secured in place using clips, guides, or other hardware that prevents movement of the inflatable cold plate 102 outside of the slot.

In some embodiments, the inflatable cold plate 102 includes a material of the inflatable cold plate 102 facing the memory cards 104 to have full or substantially full contact with of at least a top surface of the components 302 of the memory cards 104. In other embodiments, the material of the inflatable cold plate 102 also contacts at least some of the printed circuit board (“PCB”) or other surface below the components 302. In some embodiments, one or both surfaces of the inflatable cold plate 102 facing the two memory cards 104 include a compliant material configured to form to an irregular surface of each of the two memory cards 104. As used herein, a compliant material is a material with elastic properties that has an ability to conform to irregular surfaces. In the embodiments, the compliant material of the sides of the inflatable cold plate 102 have an elasticity and are elastic enough to mold to the shape of the components 302 and possibly to also reach the PCB of the memory cards 104. In other embodiments, the compliant material of the inflatable cold plate 102 facing the memory cards 104 is elastic enough to contact a portion of the surfaces of the components 302 sufficient to cool the memory cards 104 while not touching the entire top surfaces of the components 302. In some embodiments, the sides of the inflatable cold plates 102 are configured to exert a chosen amount of pressure on the components 302 that is above a lower pressure limit and below an upper pressure limit where a range between the upper and lower pressure limits is enough for cooling but low enough to prevent damage due to moving the memory cards 104 an unwanted amount.

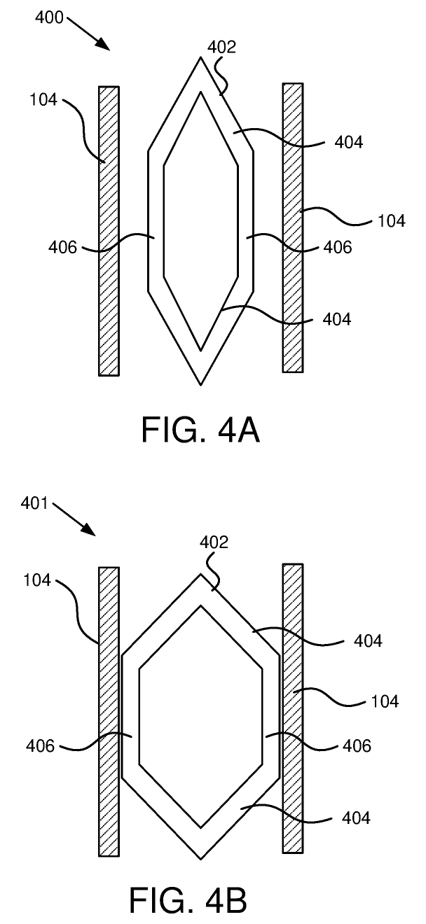

In some embodiments, the inflatable cold plates 102 include edges of the sides facing the memory cards 104 that are designed to expand. Two such designs are depicted in FIGS. 4A, 4B, 5A, 5B, 6A, 6B, 7A, and FIG. 7B. In some embodiments, edges of the sides of the inflatable cold plates 102 facing the memory cards 104 are made of a different material, a more elastic material, etc. to allow stretching around the perimeter of the sides facing the memory cards 104.

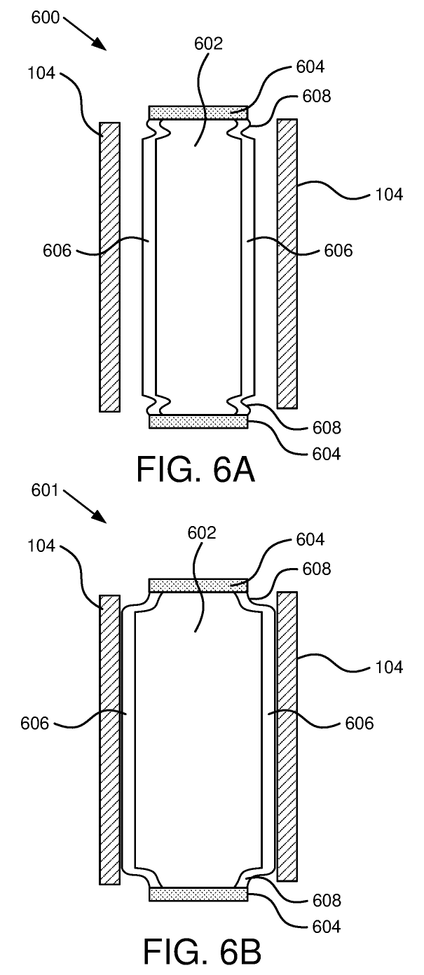

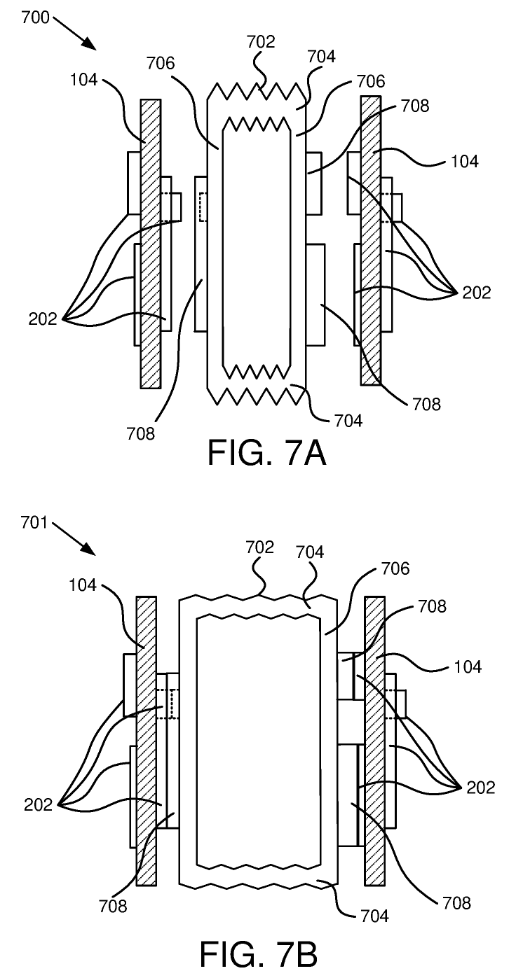

In some embodiments, at least sides of the inflatable cold plate 102 facing the memory cards 104 include a thermally conductive material. In some embodiments, a thickness of the sides of the inflatable cold plates 102 facing the memory cards 104 are thin enough to allow heat from the components 302 of the memory cards 104 to pass through to the fluid in the fluid cooling system. In some embodiments, the thermally conductive material is elastic such as silicone rubber, latex, or the like. In some embodiments, the inflatable cold plate 102 is made of more than one material. In some examples, the inflatable cold plate 102 includes a rigid frame made of plastic, metal, etc. with an elastic material on the sides facing the memory cards 104, as depicted in FIG. 6A and FIG. 6B. In some embodiments, inflatable cold plate 102 forms an irregular exterior to mirror the surface of the memory cards 104, as depicted in FIG. 7A and FIG. 7B.

FIG. 4A is a schematic block diagram 400 illustrating a cross section of memory cards 104 with an uninflated inflatable cold plate 402 for cooling with a V-shaped end 404, according to various embodiments. FIG. 4B is a schematic block diagram 401 illustrating the memory cards 104 and inflatable cold plate 402 of FIG. 4A where the inflatable cold plates are inflated, according to various embodiments. In some embodiments, the inflatable cold plate 402 is substantially similar to the inflatable cold plate 102 of FIGS. 1, 2, 3A, and FIG. 3B.

The inflatable cold plate 402 is located between two memory cards 104. In some embodiments, the inflatable cold plate 402 has hexagonal cross-section with a V-shaped end 404. The inflatable cold plate 402 has a relatively narrow cross-sectional width when not pressurized by the fluid cooling loop allowing the inflatable cold plate 402 to be placed in the slot between two memory cards 104. When pressurized by the fluid in the fluid cooling loop, the V-shaped ends flex and the inflatable cold plate 402 expands in width to contact the memory cards 104. In some embodiments, at least the sides 406 of the inflatable cold plate 402 are made of a semi-rigid material. In these embodiments, the inflatable cold plate 402 is rigid such that it maintains its shape but flexible enough to expand in a direction to contact the memory cards 104. In some embodiments, the V-shaped ends 404 flex and expand. In other embodiments, corners of the hex-shaped inflatable cold plate 402 flex and depicted straight sections of the inflatable cold plate 402 are rigid or semi-rigid. In some embodiments, the inflatable cold plate 402 is of a unitary material and expands in a desired direction towards the memory cards 104 due to the hexagonal shape, a reduced thickness at the corners, the V-shaped ends 404, and the like. In other embodiments, the inflatable cold plate 402 is made from more than one material. For example, the corners of the inflatable cold plate 402 may be a of a more pliable material than other portions of the inflatable cold plate 402.

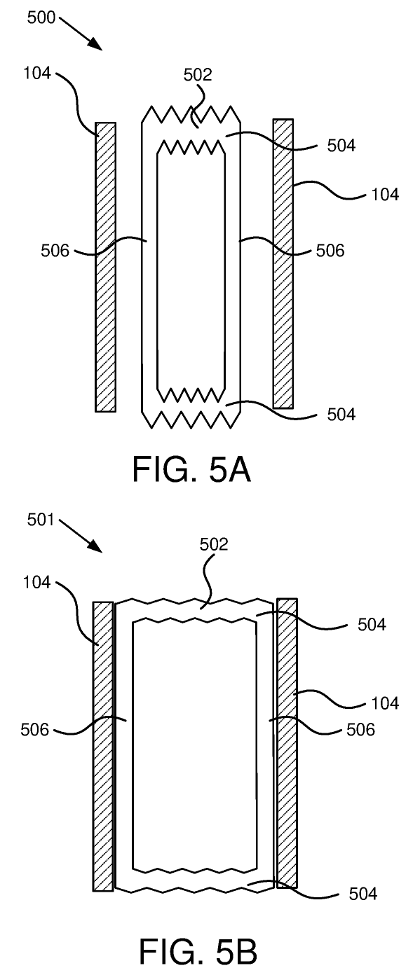

FIG. 5A is a schematic block diagram illustrating a cross section 500 of memory cards 104 with another uninflated inflatable cold plate 502 for cooling with a bellows-type end 504, according to various embodiments. FIG. 5B is a schematic block diagram 501 illustrating the memory cards 104 and inflatable cold plates 502 of FIG. 5A where the inflatable cold plates 502 are inflated, according to various embodiments. In some embodiments, the inflatable cold plate 502 is substantially similar to the inflatable cold plate 102 of FIGS. 1, 2, 3A, and FIG. 3B.

The inflatable cold plate 502 is located between two memory cards 104. In some embodiments, the inflatable cold plate 502 has a bellows-type end 504 with a narrow cross section with multiple ridges along the top and bottom when uninflated but when fully expanded, the bellows-type ends 504 expand while the sides 506 move towards the memory cards 104. In some embodiments, the entire inflatable cold plate 502 is made of a unitary material. In other embodiments, the bellows-type ends 504 are made from a different material than the sides 506. In the embodiments, in some cases the sides 506 are thicker than the bellows-type ends 504. In some examples, the bellows-type ends 504 are made of a more flexible material than the sides 506.

FIG. 6A is a schematic block diagram illustrating a cross section 600 of memory cards 104 with another uninflated inflatable cold plate 602 for cooling with a frame and expandable connectors 608, according to various embodiments. FIG. 6B is a schematic block diagram 601 illustrating the memory cards 104 and inflatable cold plates 602 of FIG. 6A where the inflatable cold plates 602 are inflated, according to various embodiments. In some embodiments, the inflatable cold plate 602 is substantially similar to the inflatable cold plate 102 of FIGS. 1, 2, 3A, and FIG. 3B.

In the embodiments, the ends of the inflatable cold plate 602 are part of a frame 604 where sides 606 are connected with expandable connectors 608. In some embodiments, the expandable connectors 608 and sides 606 are the same material where the expandable connectors 608 may be thinner, may be shaped for expansion, etc. and the sides 606 may be thicker so that expansion of the inflatable cold plate 602 results in the sides 606 moving towards the memory cards 104. In other embodiments, the expandable connectors 608 are of a different material than the sides 606.

FIG. 7A is a schematic block diagram illustrating a cross section 700 of memory cards 104 with another uninflated inflatable cold plate 702 for cooling similar to the inflatable cold plate 502 of FIG. 5A and FIG. 5B with sides with variable thickness to match components of the memory cards, according to various embodiments. FIG. 7B is a schematic block diagram 701 illustrating the memory cards and inflatable cold plates of FIG. 7A where the inflatable cold plates are inflated, according to various embodiments. In some embodiments, the inflatable cold plate 702 is substantially similar to the inflatable cold plate 102 of FIGS. 1, 2, 3A, and 3B.

The ends 704 are a bellows-type end, as in FIG. 5A and FIG. 5B. The sides 706 include one or more gap pads 708 positioned on one or both surfaces of the sides 706 of the inflatable cold plate 702 facing the two memory cards 104 to contact one or more components 302 of the memory cards 104. A gap pad 708 is a material that is typically pliable and has good heat transfer properties and is often used to transfer heat between an component 202 and some type of heat transfer device.

In the depicted embodiments, the gap pads 708 are connected to the surfaces of the sides 706 of the inflatable cold plate 702 facing the memory cards 104 and are positioned to align with the components 302. In some embodiments, the gap pads 708 are a uniform thickness and conform to the various components 302 of varying heights from the PCB of the memory cards 104. In other embodiments, the gap pads 708 are of varying thicknesses where the thicknesses are designed to match a distance that the various components 302 extend from the PCB of the memory cards 104. In other embodiments, the sides 706 do not have gap pads 708 but instead have a varying thickness with protrusions (matching the gap pads 708 of FIGS. 7A and 7B) sized, positioned and shaped to contact the components 302 when the inflatable cold plate 702 is inflated.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
an inflatable cold plate configured for placement in a slot between two memory cards connected to a motherboard of a computing device, wherein:
the inflatable cold plate expands to contact the two memory cards in response to pressure from a cooling fluid; and
the inflatable cold plate is configured to transfer heat from the two memory cards to the cooling fluid,
wherein the inflatable cold plate is in fluid communication with a fluid pump configured to:
pump the cooling fluid through the inflatable cold plate at a sufficient pressure to pressurize the inflatable cold plate against the two memory cards; and
circulate the cooling fluid through the inflatable cold plate to transfer heat from the inflatable cold plate.

2. The apparatus of claim 1, wherein the two memory cards are two dual in-line memory modules (“DIMMs”).

3. The apparatus claim 1 wherein the inflatable cold plate is configured to expand in a direction towards a side of each of the two memory cards in response to the fluid pump pumping the cooling fluid.

4. The apparatus of claim 1, wherein one or both surfaces facing the two memory cards comprise a compliant material configured to form to an irregular surface of each of the two memory cards.

5. The apparatus of claim 1, wherein one or both surfaces facing the two memory cards comprise an irregular shape configured to form to a corresponding irregular surface of each of the two memory cards.

6. The apparatus of claim 1, wherein sides of the inflatable cold plate other than surfaces facing the two memory cards expand less than the surfaces facing the two memory cards.

7. The apparatus of claim 6, wherein the sides of the of the inflatable cold plate other than surfaces facing the two memory cards are configured to be rigid.

8. The apparatus of claim 1, further comprising the fluid pump and a heat exchanger, the heat exchanger positioned in a cooling loop in fluid communication with the fluid pump and the inflatable cold plate and positioned to remove heat from the cooling fluid.

9. The apparatus of claim 8, wherein the heat exchanger is a first heat exchanger and is coupled to a secondary cooling loop, the secondary cooling loop is coupled to a secondary heat exchanger configured to expel heat to air in a location away from the computing device.

10. The apparatus of claim 8, wherein the heat exchanger is configured to expel heat to air in a location away from the computing device.

11. The apparatus of claim 1, further comprising the fluid pump, wherein the cooling fluid is air and the fluid pump and inflatable cold plate are in fluid communication via an open loop, wherein air exiting the inflatable cold plate is expelled to a location external to the computing device and/or a space housing the computing device.

12. The apparatus of claim 1, wherein the inflatable cold plate further comprises one or more gap pads positioned on one or both surfaces of the inflatable cold plate facing the two memory cards to contact one or more components of at least one of the two memory cards.

13. The apparatus of claim 1, wherein the cooling fluid is helium.

14. A system comprising:
a fluid pump; and
a computing device further comprising:
a motherboard;
at least two memory cards connected to the motherboard; and
at least one inflatable cold plate configured for placement in a slot between two memory cards of the at least two memory cards connected to the motherboard, wherein:
the at least one inflatable cold plate expands to contact the two memory cards in response to pressure from a cooling fluid; and
the at least one inflatable cold plate is configured to transfer heat from the two memory cards to the cooling fluid,
wherein the at least one inflatable cold plate is in fluid communication with the fluid pump configured to:
pump the cooling fluid through the inflatable cold plate at a sufficient pressure to pressurize the inflatable cold plate against the two memory cards; and
circulate the cooling fluid through the inflatable cold plate to transfer heat from the inflatable cold plate.

15. The system of claim 14, further comprising a heat exchanger, the heat exchanger positioned in a cooling loop in fluid communication with the fluid pump and the inflatable cold plate and positioned to remove heat from the cooling fluid.

16. The system of claim 15, wherein the heat exchanger is a first heat exchanger and is coupled to a secondary cooling loop, the secondary cooling loop is coupled to a secondary heat exchanger configured to expel heat to air in a location away from the computing device.

17. The system of claim 15, wherein the heat exchanger is configured to expel heat to air in a location away from the computing device.

18. The system of claim 14, wherein the cooling fluid is air and the fluid pump and inflatable cold plate are in fluid communication via an open loop, wherein air exiting the inflatable cold plate is expelled to a location external to the computing device and/or a space housing the computing device.

19. The system of claim 14, wherein the cooling fluid is helium.

20. An apparatus comprising:
an inflatable cold plate configured for placement in a slot between two dual in-line memory modules (“DIMMs”) connected to a motherboard of a computing device, wherein:
the inflatable cold plate expands to contact the two DIMMs in response to pressure from a cooling loop; and
the inflatable cold plate is configured to transfer heat from the two DIMMs to the cooling loop,
wherein the inflatable cold plate is in fluid communication with a fluid pump configured to:
pump helium in a cooling loop through the inflatable cold plate at a sufficient pressure to pressurize the inflatable cold plate against the two DIMMs; and
circulate the helium through the cooling loop of the inflatable cold plate to transfer heat from the inflatable cold plate to an external heat exchanger within the cooling loop.
